(19) United States
(12) Patent Application Publication
(10) Pub. No.: US 2005/0007127 A1
(43) Pub. Date: Jan. 13, 2005

(54) Digital RF bridge

(76) Inventor: Paul B. Cram, Mansfield, GA (US)

Correspondence Address: PAUL B. CRAM, 3055 WHITE PINE LANE, MANSFIELD, GA, 30055, US

(21) Appl. No.: 10/614,703

(22) Filed: Jul. 7, 2003

(51) Int. Cl. G01R 27/26

(52) U.S. Cl. 324/680

(57) ABSTRACT

A bridge of a twin-T type may have been proposed before but not in the form and function of this DIGITAL RF BRIDGE. In the DETAILED DESCRIPTION and MATHEMATICS writings of this application I describe the DIGITAL RF BRIDGE and it's process as being unique. The computer used here will be of ordinary origin but equipped with the special software. The printer is common and standard The signal generator is common, same as used regularly in bridge measurement processes. The null detector will normally be constructed as a part of the main bridge unit, well shielded and tunable.

The device for measuring capacity values of C1 and C2 will normally be constructed as part of the main bridge unit and will work with the computer software to derive capacity in picofarads The Digital RF Bridge is dependent upon the computer and it's software to execute it's functions and, likewise, the computer process is dependent upon the functions of the Bridge unit. In the absence of either one, the process cannot exist.

### BACKGROUND OF THE DIGITAL RF BRIDGE

Especially in the broadcast industry, but not only in the broadcast industry, there has always been a need for an instrument capable of measuring reactance and resistance of components and antennas. Bridges presently manufactured for this use are fitted with multiple dials, each with calibration markings. Accuracy of these instruments depends upon settings of these dials. In this environment there is also a need for an RF Bridge that will measure higher impedance unknowns. Bridges that I have used for the past 50 years are not directly applicable to measurements of impedance that include a resistive component above 1000 ohms.

I have developed a bridge that requires no eye readings of the dials and that will make these measurements with better accuracy, of higher impedance unknowns and with less trouble. The frequency range within which it will work is only dependent upon mechanical aspects, the physical characteristics of the components for higher or lower frequencies.

The bridge I speak of has been named DIGITAL RF BRIDGE. It is my invention and is the subject of this application for patent. In fewest words, the invention can be described as a computer with a sampling system extending into the Bridge and programmed so as to calculate unknowns from electronic measurements of increments of capacitance from within the bridge circuitry.

### BRIEF SUMMARY OF THE INVENTION

This invention is partially the central unit and totally the collection of several units connected so as to support a unique procedure in the measurements of resistance and reactance at radio frequencies. The procedure is unique in that the central unit, the DIGITAL RF BRIDGE, transmits data to an ordinary notebook computer equipped with special software and that there is never a need for eye readings of controls on the bridge and that the calculations use only increments of C1 and C2.

The improvements are:
(a) That this method of measurement eliminates errors due to residual and stray capacitance
(b) That this method eliminates errors in eye readings.)
(c) That this procedure is easier and faster than procedures with existing test equipment.)
(c) That repeatability is improved because of the unbalanced arrangement of parts.

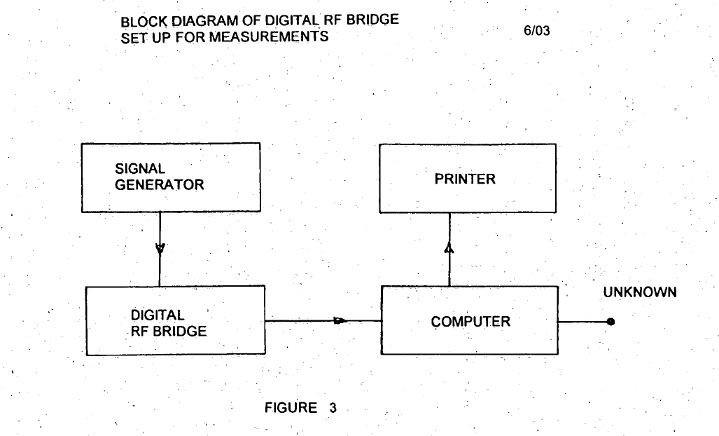

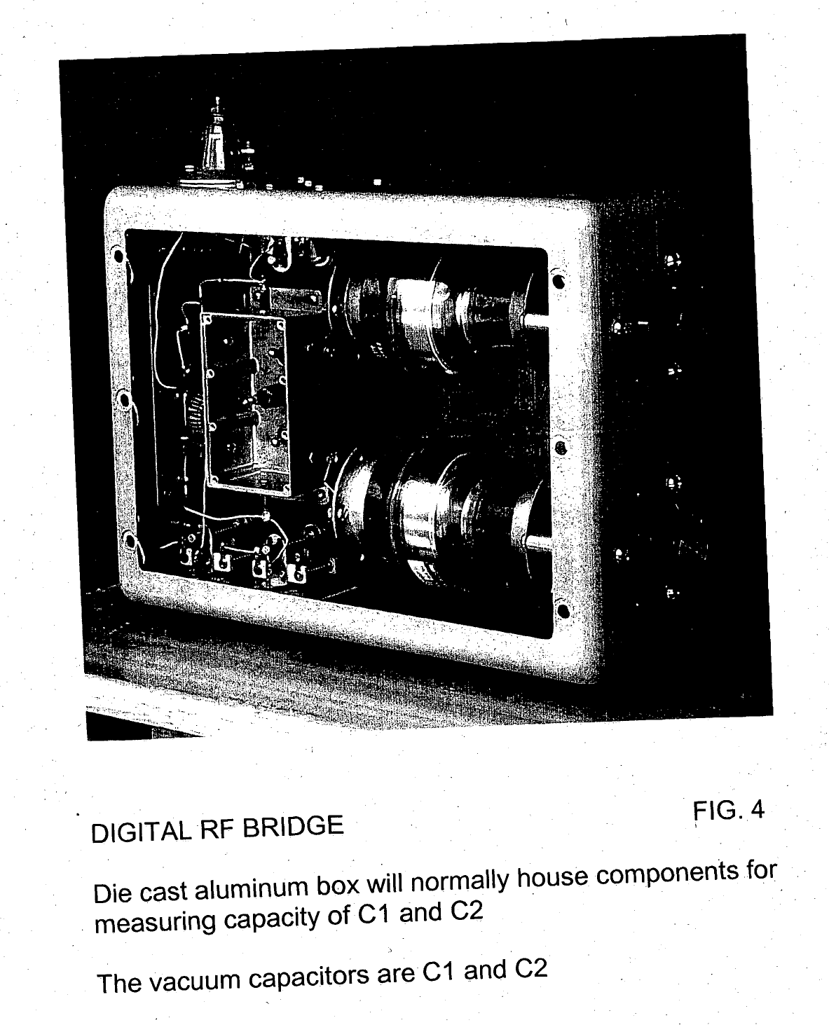

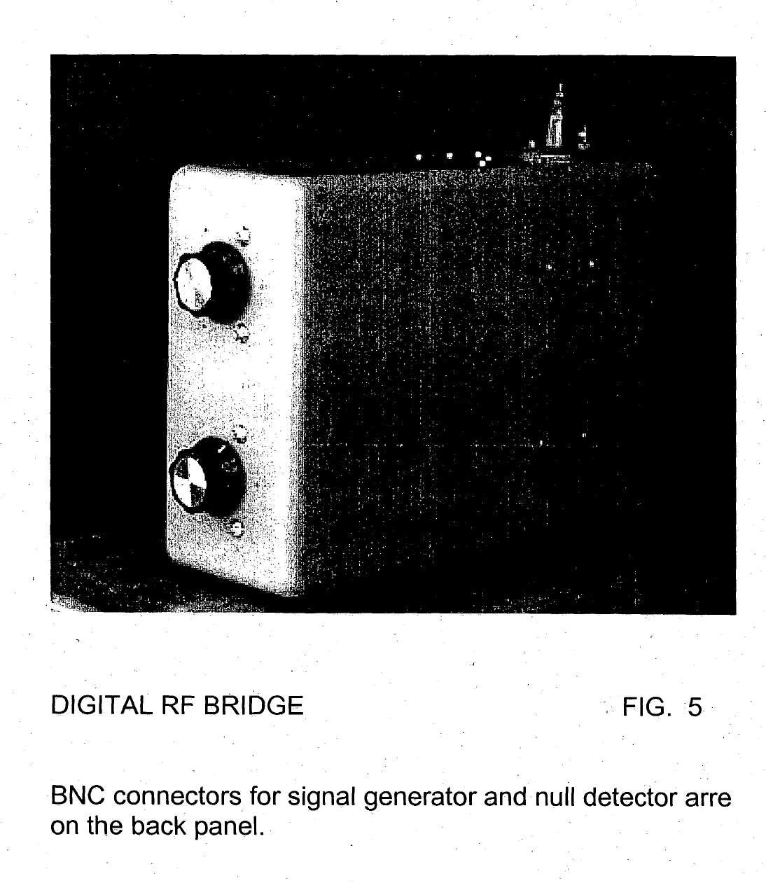

The procedure:
(a) With the bridge connected as indicated in FIG. 3, and with open unknown terminals, adjust C1 and C2 for deepest null.)
(b) Press buttons for C1 and C2, transmitting capacitance information to the computer.)
(c) Connect the unknown, readjust C1 and C2 for null.)
(d) Press buttons to transmit new capacitance information to the computer. The computer will convert these pairs of capacitance readings to delta C1 and delta C2 and, with known constants of the bridge, will calculate impedance of the unknown. Delta C1 is indicative of resistance and delta C2 is indicative of reactance.

### DETAILED DESCRIPTION OF THE INVENTION

See FIG. 3. The Digital RF Bridge is an adaptation and variation of the conventional twin-t network. The T labeled A consists of resistance and capacitive reactance while the T labeled B has a shunt leg consisting of resistance, positive reactance and negative reactance in a parallel combination across which the unknown terminals are connected. This unusual configuration allows measurements of both positive and negative reactance with the shunt leg of the B network and resistance only with the shunt leg of the A network. The schematic diagram labeled FIG. 2 shows that the variable capacitor C! forms the shunt leg of A network and the variable capacitor C2 forms part of the shunt leg of B network. Increments of reactance of these two variable capacitors are used in the calculations of parallel resistance and reactance components of the unknown impedance under measurement.

As a part of the Digital RF Bridge, there is an electronic device that sends information to the computer concerning the adjustments of C1 and C2. Values of C1 and C2 are sent to the computer with initial balance conditions and conditions of measurement with an unknown connected to the bridge. The differences between these two sets of measurements are used to calculate resistance and reactance of the unknown.

As an example of the procedure, we will do a detailed explanation of each step in the measuring of the drive point impedance of a vertical steel tower as the antenna for a clear channel station on a frequency of 1040 kilohertz. The tower will typically be ⅝ wavelength in height, 180 meters, and the base drive point impedance will be quite high. During the period of time for these measurements it is assumed the station will be “off the air”.

The bridge is connected as indicated by block diagram FIG. 3. A conventional signal generator is connected to the bridge input terminals and it's frequency is set exactly to 1040 kilohertz. The well shielded and tuned null detector is reading voltage at the output terminals of the bridge. The data cables will be installed, connecting the bridge to the notebook computer. The computer will be booted up and running the special software written for this purpose.

With the unknown terminals “open” the capacitors C1 and C2 will be adjusted for a null. At this point, the first data is sent to the computer. This is data with which the computer will calculate the capacitor C1 and C2 values in picofarads. Next, the antenna feed point is connected to the unknown terminals of the bridge and a new null condition is set. New values of C1, C2 are sent to the computer. The computer subtracts measurement balance values of C1 and C2 from the respective initial balance values. With these delta C1 and delta C2 values and with known constants of the bridge, the computer proceeds to calculate resistance and reactance of the antenna feed point. Print-out is provided. The print-out can be simple or comprehensive, as the need be.

Bridge measurement of it's own capacitors C1 and C2 is accomplished by the formation of an oscillatory circuit with the C1 or C2 and a known inductor. With gating and counting the frequency of the oscillation is determined. Frequency is then applied in the formula within the computer:
C=1/Omega²L (Where omega=2 Pi f)
Delta C=Cb−Ca (where Ca is the initial balance value and Cb is the value when the bridge is in balance with the Unknown connected.)

The values of delta C1 and delta C2 are applied in the computer to calculate resistance and reactance of the unknown that is being measured by the Digital RF Bridge.

Various configurations of T networks can be used in parallel to form bridge circuits. The one I have chosen seems to allow best range of resistance and reactance and will allow measurements of both positive and negative reactance. In any case, the currents of the output legs must add to zero. Input impedance of the null detecting instrument is of no consequence because ratio of the current values is maintained. It is also true that internal impedance of the signal generator does not affect accuracy. This is because input current values are governed by input impedances of the separate networks and because only the relationship of these currents is considered in the calculations.

Mathematics of the Digital RF Bridge

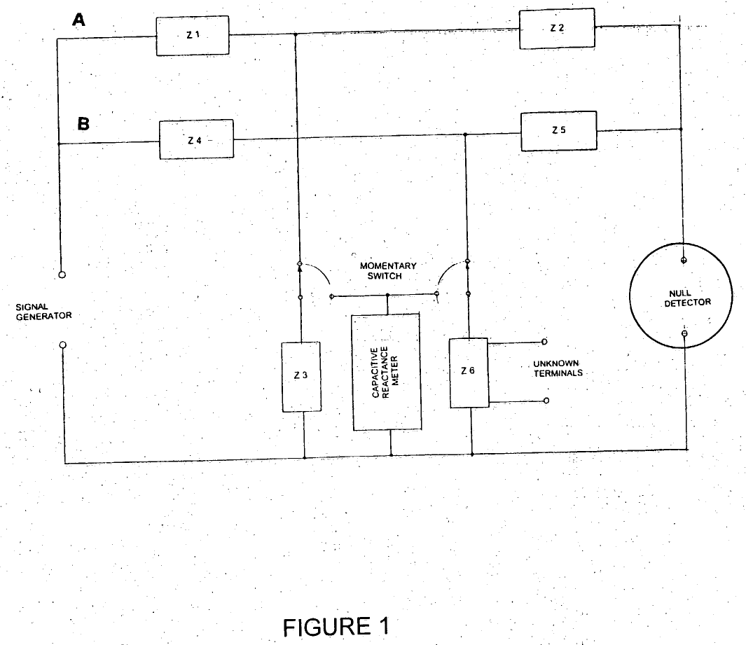

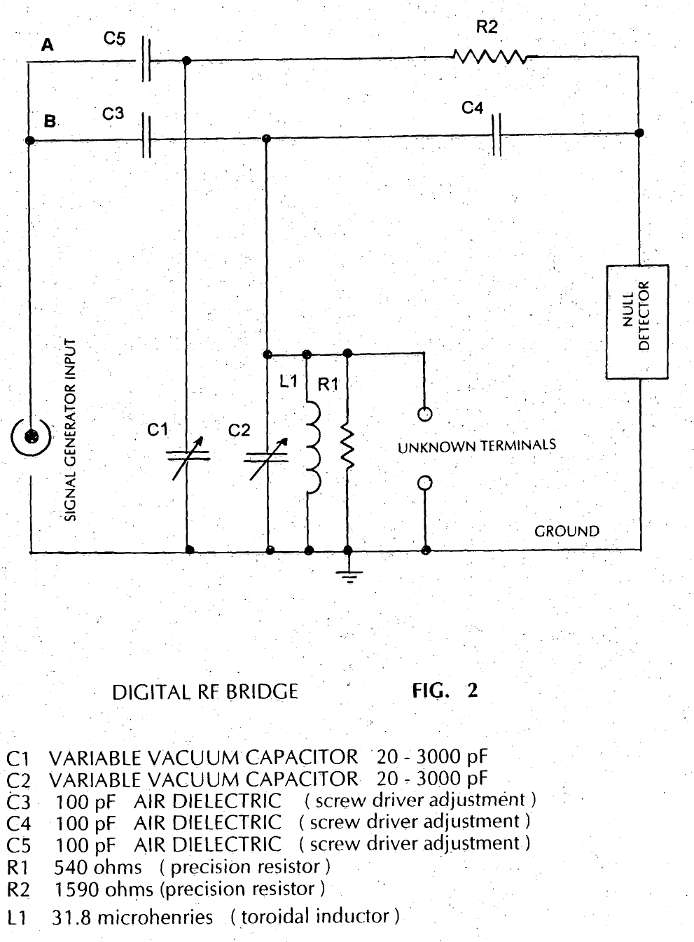

This discussion relates to FIGS. 1 and 2.

Let there be a short circuit in place of the null detector.

Let the signal generator voltage be represented as Eo+j0

Let the voltages across shunt impedances be E3 and E6

Let the frequency be 1.0 megahertz
E3=Eo−E1
E6=Eo−E4

All quantities are considered to be complex.
Current in output leg of network A=Ia2=E3/Z2
Current in output leg of network B=Ib5=E6/Z5

These two current values must cancel for null condition. It is said that the bridge is “balanced” when in null condition. Initial balance is with the unknown terminals open.

An assignment of values for components of the two t-networks is shown in FIG. 2, giving a state of “balance”. It will be noted that the shunt leg Z6 consists of three components connected in parallel and that the unknown terminals are also in parallel with Z6.

In initial balance condition, for this experiment, the three components of Z6 are:
540+j0 Resistance 540 ohms
0+j199.7 Inductor 31.8 uH
0−j280.3 Capacitor 568 pF

Combining C2 and L1 we have a 540 ohm resistor in parallel with 694.49 ohms of inductive reactance.

If the unknown is simply a capacitor, a downward adjustment of C2 will put the system back in balance. If the unknown is purely inductive, an upward adjustment of C2 will be required to put the system back in balance. If the unknown is both resistive and reactive, adjustments of both C1 and C2 will be required. The indications of resistance and reactance will be independent of each other, delta C1 for calculating resistance and delta C2 for calculating reactance.

Mathematics

The delta values are differences in C1 and C2 settings with initial balance and then balance with the unknown connected.
Example: deltaC2=C2a−C2b
where C2a and C2b are capacitor settings with initial balance and measurement balance settings, respectively.
   Xp=1/2 Pi f deltaC2

It is important to note that the sign of the calculated unknown reactance is correct if the negative reactance of C2 in unknown balance condition is subtracted from negative reactance of C2 while in initial balance condition.

Now we look at what happens when the unknown is a non inductive resistor. There is a change in transfer characteristic of network B and restoration of balance can only be accomplished by varying the transfer characteristic of network A, this by varying reactance of it's shunt leg C1.
Rp=1/R2(deltaC1/C5)C2²omega²
where omega=2 Pi f Pi=3.14159
and where Xp and Rp are parallel Components of the unknown

Let it be established that the shunt leg of network B, consisting of resistance and both polarities of reactance, will always have a positive resultant characteristic because the inductive reactance is always less than the capacitive reactance in parallel with it. The circuit is approaching resonance on the inductive side and the inductive reactance can thereby be varied over a wide range.

When the unknown consists of both resistance and reactance it will be necessary to adjust both C1 and C2 for restoration of balance. Delta values of these capacitors are applied in the appropriate formulae.

Specification f the Digital RF Bridge Assembly

For measurements of reactance and resistance within the frequency band as specified¹
Accuracy:
   Commercial, plus/minus 5 percent
   Laboratory, plus/minus 2 percent
Central unit: Digital RF Bridge
Accessories:
   Signal generator
   Null Detector
   Notebook Computer with Bridge Software
   Connecting cables
      1 Frequency band can be specified to one gigahertz

1. What I claim as my invention is a unit of test equipment, named the digital RF bridge, a special adaptation of the twin tee network and a contributor to the unique method of measuring impedance quantities in the radio frequency bands. It is fully described in a section of this application named DETAILED DESCRIPTION OF THIS INVENTION.
